(19) United States
(12) Patent Application Publication
(10) Pub. No.: US 2023/0356628 A1
(43) Pub. Date: Nov. 9, 2023

(54) THERMAL CONTROL DEVICE WITH A TUBING AND METHOD OF CONNECTING OF A TUBING TO A THERMAL CONTROL DEVICE

(71) Applicant: VALEO SYSTEMES THERMIQUES, La Verrirere (FR)

(72) Inventors: Donald BOYD, La Verriere (FR); Roy RISKI, La Verriere (FR); David LOHMUELLER, La Verriere (FR)

(73) Assignee: VALEO SYSTEMES THERMIQUES, La Verriere (FR)

(21) Appl. No.: 17/735,570

(22) Filed: May 3, 2022

(51) Int. Cl. B60L 58/24; F28F 9/013; F28F 1/42

(52) U.S. Cl. CPC B60L 58/24; F28F 9/013; F28F 1/422; F28F 2275/04; F28F 2275/08; F28F 2275/20

(57) ABSTRACT

A thermal control device has a thermal control device base, a connection block attached to the thermal control device and a tubing for a heat exchange fluid attached to the connection block. The tubing has a tubing extension axis and a tubing side wall. The connection block includes a connection block receiving section which receives a part of the tubing side wall. The connection block is configured to facilitate heat exchange between the tubing side wall and the thermal control device.

### TECHNICAL FIELD

The present invention relates to a thermal control device, in particular to a cooling or heating device, in particular for an electrical component.

### BACKGROUND OF THE INVENTION

Vehicle batteries, in particular for electric vehicles or hybrid vehicles, must be kept at desired temperature as much as possible, which is why so-called thermal control devices for vehicle batteries are used. These thermal control devices may comprise cooling plates through which a cooling liquid flows. Similar considerations are valid for electronic devices such as e.g. electronic control units, which too operate optimally within a certain temperature range.

The thermal control devices can serve as a point for attachment of tubing carrying the heat exchange fluid, such as a refrigerant, e.g. R134a, R1234yf or R744, or a coolant, e.g. glycol based coolant. This tubing can carry the heat exchange fluid to or from the thermal control device, or it can even not be fluidly connected to it at all. In any case, the connection needs to be secure and versatile.

The invention aims at providing a thermal control device with a connection block able to receive tubing, which would provide the above-mentioned advantages.

### BRIEF SUMMARY OF THE INVENTION

The object of the invention is, among others, a thermal control device, comprising: a thermal control device base; a connection block attached to the thermal control device base; a tubing for a heat exchange fluid attached to the connection block, with the tubing having a tubing extension axis and a tubing side wall; and wherein the connection block includes a connection block receiving section, including connection block grooves, for receiving a part of the tubing side wall.

In one embodiment, the connection block grooves run substantially parallel to the tubing extension axis.

In one embodiment, the tubing has tubing inner grooves on a tubing inner surface.

In one embodiment, the tubing has tubing outer grooves on a tubing outer surface.

In one embodiment, the connection block receiving section includes an open trough.

In one embodiment, the connection block receiving section includes a through-hole.

In one embodiment, the tubing is divided into a first tube with a first tube extension axis and a second tube with a second tube extension axis, with the first tube and the second tube being received at the connection block receiving section and being connected fluidly by the connection block.

In one embodiment, the first tube extension axis is collinear with the second tube extension axis.

In one embodiment, the first tube extension axis is perpendicular to the second tube extension axis.

In one embodiment, the first tube and the second tube are connected to the connection block receiving section by a threaded connection.

In one embodiment, the connection block is mechanically attached to the thermal control device.

In one embodiment, the connection block is brazed to the thermal control device.

Another aspect of the invention is an electric vehicle comprising a thermal control device including: a thermal control device base; a connection block attached to the thermal control device base; a tubing for a heat exchange fluid attached to the connection block, with the tubing having a tubing extension axis and a tubing side wall; and wherein the connection block includes a connection block receiving section, including connection block grooves, for receiving a part of the tubing side wall.

Another aspect of the invention is a method of connecting of a tubing to a thermal control device, comprising: providing a connection block with a connection block receiving section including grooves; providing the tubing; fixing the tubing to the connection block; and attaching the connection block to the thermal control device.

In one embodiment, fixing of the tubing includes aligning the tubing in the connection block so that at least a portion of a tubing side wall contacts with the receiving section of the connection block and brazing the tubing and the connection block together.

In one embodiment, the fixing the tubing includes screwing the tubing into the connection block receiving section.

In one embodiment, the tubing includes a first tube and a second tube, with the first tube and the second tube being independently attached to the connection block receiving section.

### BRIEF DESCRIPTION OF THE DRAWINGS

The present invention will be described in greater detail below with reference to the drawings. In the drawings:

FIG. 1 shows a thermal control device according to the invention in a perspective view;

FIG. 2 shows a vertical cross-section of the thermal control device of FIG. 1;

FIG. 3 shows another embodiment of the thermal control device in a perspective view;

FIG. 4 shows a horizontal cross-section of the thermal control device of FIG. 3;

FIG. 5a shows a vertical cross-section of a variant of the thermal control device of FIG. 3;

FIG. 5b shows a vertical cross-section of another variant of the thermal control device of FIG. 3;

FIG. 6 shows another embodiment of the thermal control device in a perspective view;

FIG. 7 shows a horizontal cross-section of the thermal control device of FIG. 6;

FIG. 8 illustrates a variant of a tubing in a perspective view;

FIG. 9 illustrates another variant of a tubing in a perspective view;

FIG. 10 illustrates another variant of a tubing in a perspective view;

FIG. 11 illustrates another variant of a tubing in a perspective view; and

FIG. 12 shows a method of connecting of a tubing to a thermal control device according to the invention.

### DETAILED DESCRIPTION OF THE INVENTION

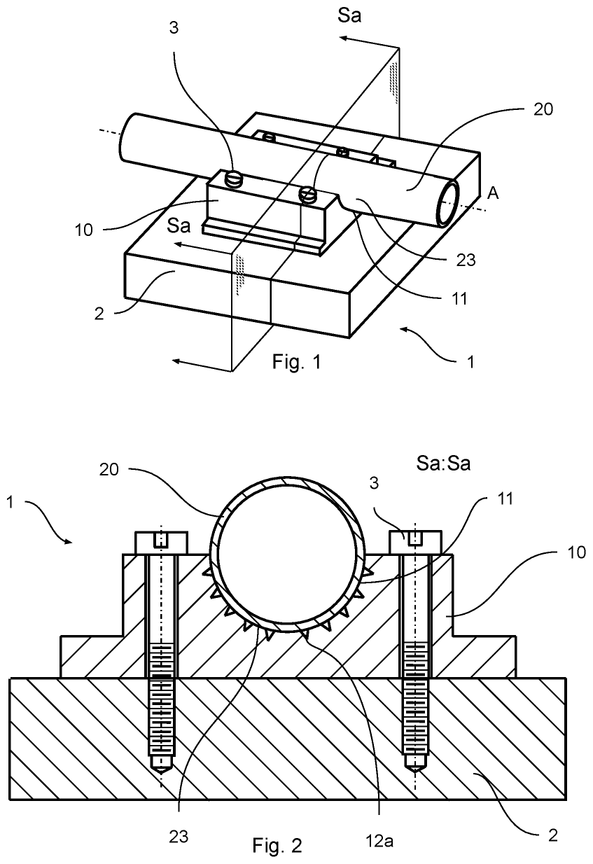

FIG. 1 shows a thermal control device 1 according to the invention in a perspective view. In general, the thermal control device 1 is a device for controlling, i.e. influencing, the temperature of another element or component. The thermal control device 1 can be a heat exchanger, in which case it is only schematically illustrated and can assume more elaborated structures. In one embodiment, the thermal control device 1 can be a battery cooler serving as a heat exchanger for cooling and/or heating of a battery of an electric vehicle. In another embodiment, the thermal control device 1 can be a heat exchanger for cooling and/or heating of an electronic device. In any case, the thermal control device 1 comprises a thermal control device base 2 to which further components can be attached. In one embodiment, the thermal control device base 2 can be a heat exchanger housing through which the heat exchange fluid is enabled to flow.

A thermal control device 1 as shown in FIG. 1 comprises a connection block 10 attached to the thermal control device base 2. A tubing 20 for a heat exchange fluid is attached to the connection block 10. Consequently, when the heat exchange fluid travels through the tubing 20, it may exchange heat with the material of the tubing 20, which in turn can transfer heat to or from the connection block 10. As the connection block 10 is connected to the thermal control device 1, effectively the heat exchange between the heat exchange fluid in the tubing 20 and the thermal control device 1, in particular the thermal control base 2 thereof is enabled.

The tubing 20 has a tubing extension axis A. In other words, the tubing 20 extends along the tubing extension axis A. The tubing 20 has a tubing side wall 23. The tubing side wall 23 is the wall of the tubing 20 which extends along the tubing extension axis A.

The connection block 10 includes a connection block receiving section 11. The purpose of the connection block receiving section 11 is to receive a part of the tubing side wall 23. It is thus understood as a shaped surface at the connection block 10 adapted to receive the tubing 20, e.g. by having a shape corresponding to the outer shape of tubing 20. The tubing side wall 23 is firmly attached to the connection block receiving section 11.

In the shown embodiment, the connection block receiving section 11 is in form of an open trough. This means that over a specific distance along the tubing extension axis A there is a portion of the tubing side wall 23 in contact with the connection block receiving section 11 and also there is a portion of the tubing side wall 23 which is not contact with the connection block receiving section 11. In this case, the top portion of the tubing side wall 23 is not in contact with the connection block receiving section 11, and consequently is not in contact with the connection block 10. In this case, the top portion of the tubing side wall 23 is the portion located on the opposite side of the tubing 20 than the connection block receiving section 11.

In the shown embodiment, the tubing 20 is attached to the connection block 10 by brazing. Other ways to attach the tubing 20 to the connection block 10 can include use of mechanical connectors, like e.g. clamps (not shown).

In the shown embodiment, the connection block 10 is attached to the thermal control device base 2 by means of connection screws 3. It is envisaged to alternatively use other connection means, such as a brazed connection. It is also possible to provide a connection block 10 integral with the thermal control device base 2.

FIG. 2 shows a vertical cross-section Sa of the thermal control device 1 of FIG. 1 with the connection block receiving section 11. In this embodiment, the connection block receiving section 11 comprises connection block grooves 12a. The connection block grooves 12a can extend parallel to each other. The connection block grooves 12a facilitate heat exchange by increasing effective heat exchange area between the tubing 20 and the connection block 10. Another advantage of the presence of the grooves 12a is that they can allow degassing of the flux during brazing process. The connection block grooves 12a can have a triangular cross-section.

In one embodiment, the connection block grooves 12a run substantially parallel to the tubing extension axis A. Consequently, they extend along the tubing side wall 23. The connection block grooves 12a can be distributed evenly along the circumference of the tubing 20.

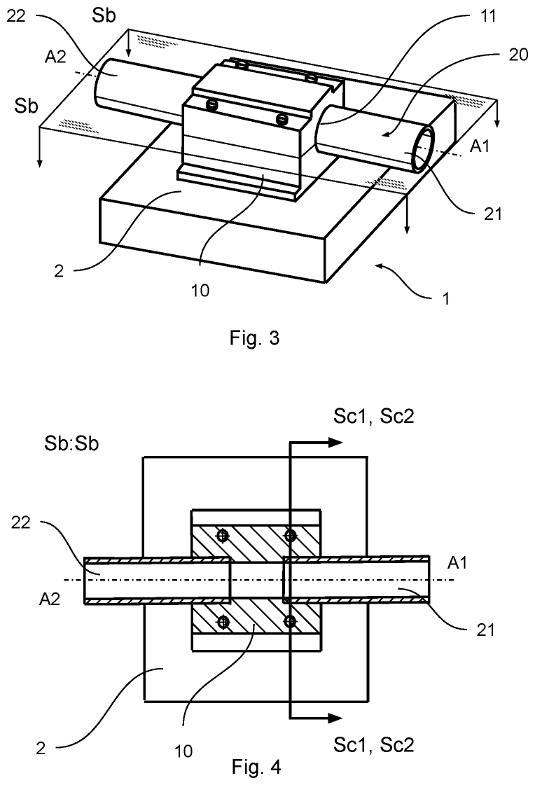

FIG. 3 shows another embodiment of the thermal control device 1 in a perspective view, while FIG. 4 shows a horizontal cross-section thereof. The connection block receiving section 11 is in form of a through-hole. This means that the connection block 10 is closed and encapsulates also the top portion of the tubing side wall 23, i.e. portion of the tubing side wall 23 located opposite to the thermal control device base 2. In this embodiment, the tubing 20 is divided into a first tube 21 and a second tube 22, the first tube 21 and the second tube 22 being received at the connection block receiving section 11 and being connected fluidly by the connection block receiving section 11. The first tube 21 has a first tube extension axis A1, and the second tube 22 has a second tube extension axis A2. In this embodiment, the first tube extension axis A1 and the second tube extension axis A2 are collinear. Also, in this example, the first and second tube extension axes A1, A2 are straight lines.

Alternatively, the first tube extension axis A1 and the second tube extension axis A2 can be not collinear, i.e. they may be shifted with respect to teach other. Also, the first and second tube extension axes A1, A2 can be curved lines.

The first tube 21 and the second tube 22 can be connected to the connection block receiving section 11 by means of a threaded connection. They can also, alternatively, be attached by brazing.

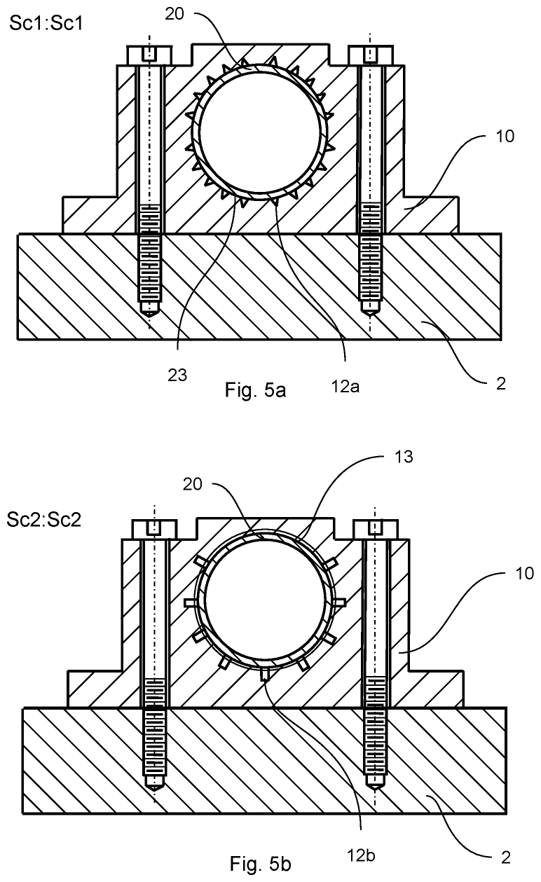

FIG. 5a shows a vertical cross-section of a variant of the thermal control device of FIG. 3. As can be seen, the connection block grooves 12a are arranged along the circumference of the tubing side wall 23. Thus, the heat exchange can be facilitated to a greater degree. Alternatively, the connection block grooves 12a could be arranged only along a part of the tubing side wall 23 circumference, if needed. It is to be noted that in this embodiment the connection block grooves 12a have a triangular shape in cross-section.

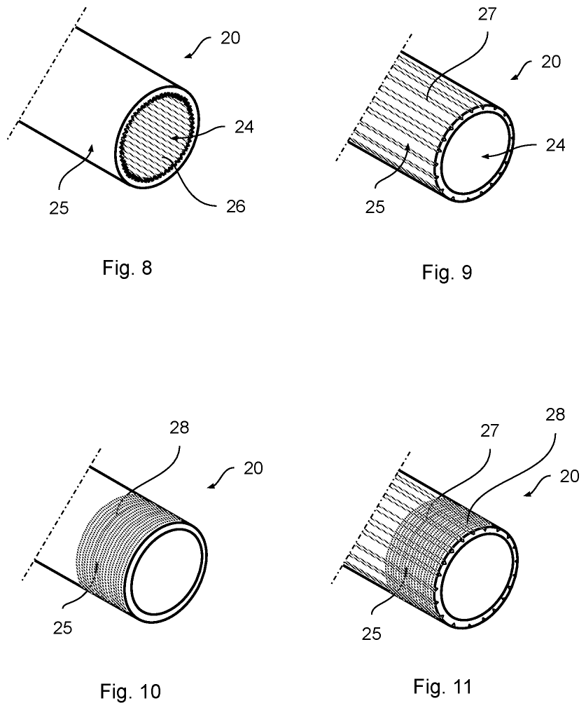

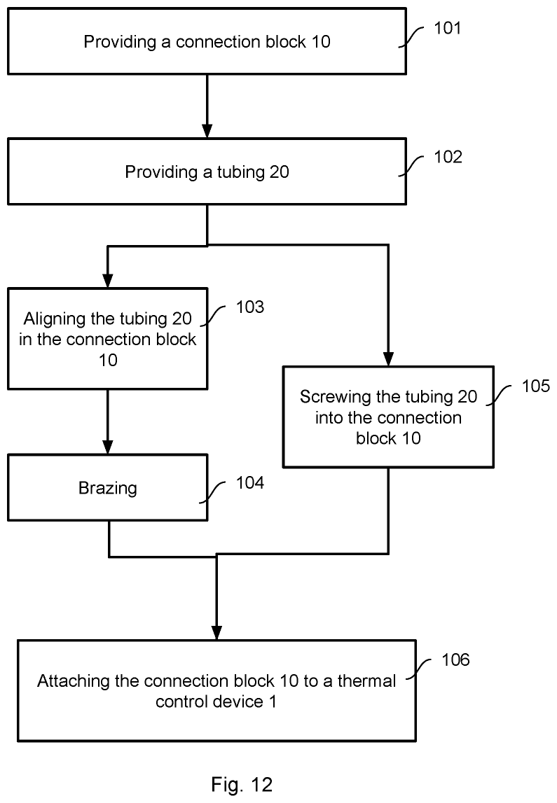

FIG. 5b shows a vertical cross-section of another variant of the thermal control device of FIG. 3. In this embodiment, there are connection block grooves 12b of rectangular shape in cross section. This shape may be more beneficial in case connection block thread 13 being present in the connection block receiving section 11. The connection block thread 13 cooperates then with respective first and second tube threads 28 which can be present on the first and second tubes 21, 22, as described in detail in relation to FIGS. 8 to 11.

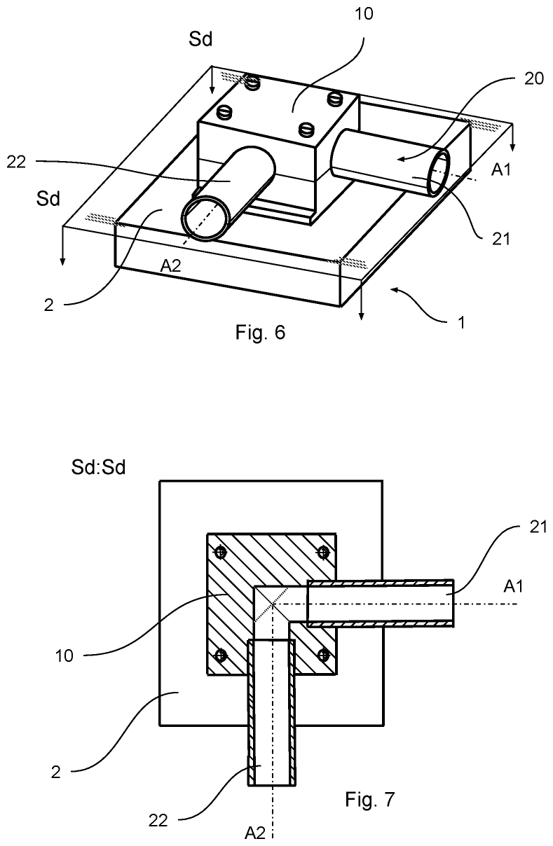

FIG. 6 shows another embodiment of the thermal control device 1 in a perspective view, while FIG. 7 shows a horizontal cross-section thereof. In this example, the first and second tube extension axes A1, A2 are straight lines. In the shown embodiment, the first tube extension axis A1 is perpendicular to the second tube extension axis A2. Consequently, the first tube 21 and the second tube 22 are in a perpendicularly arrangement with respect to each other, which may be beneficial for example from packaging point of view. Other angular arrangements are also envisaged, in particular in range of 45°-175°, e.g. 60° or 135° or 170°. Also, the first and second tube extension axes A1, A2 can be curved lines.

FIG. 8 illustrates a variant of the tubing 20 in a perspective view. The tubing 20 has tubing inner grooves 26 on tubing inner surface 24. The tubing inner grooves 26 contribute to heat exchange effectiveness by increasing the heat transfer surface in contact with the fluid. Tubing outer surface 25 in this case is smooth.

FIG. 9 illustrates another variant of the tubing 20 in a perspective view. The tubing 20 has tubing outer grooves 27 on tubing outer surface 25. The tubing outer grooves 27 contribute to heat exchange effectiveness, as well as to allow for degassing of brazing material flux and/or binder. Tubing inner surface 24 in this case is smooth.

The inner or outer tubing grooves 26, 27 can be produced by means of a spline broaching operation, e.g. at the ends of the tubing 20. Alternatively, the tubing 20 may be extruded with the inner or outer tubing grooves 26, 27 present from the outset. The inner and outer grooves 26, 27 may have a similar shape in cross-section as the connection block grooves 12a, 12b, i.e. triangular or rectangular.

Another variant (not shown) is envisaged, in which the tubing has at the same time the tubing inner grooves 26 on the tubing inner surface 24 and the tubing outer grooves 27 on the tubing outer surface 25.

For the variants described above, the tubing 20 may be attached to the connection block 10 by brazing or by mechanical means as explained earlier.

FIG. 10 illustrates a variant of the tubing 20 in a perspective view. The tubing outer surface 25 has tubing outer thread 28, intended for cooperation with the connection block thread 13 in order to securely attach the tubing 20 to the connection block 10.

FIG. 11 illustrates a variant of the tubing 20 in a perspective view. The tubing outer surface 25 has tubing outer thread 28, intended for cooperation with the connection block thread 13. The tubing outer surface 25 also has tubing outer grooves 27.

In the shown embodiments the tubing 20 has a circular shape in cross-section. There are also envisaged other tubing cross-section shapes, e.g. square or rectangular (not shown). In such cases, the tubing 20 would be attached to the connection block 10 by brazing.

In one embodiment, the thermal control device 1 comprises a plurality of connection blocks 10 to which tubing 20 is consecutively connected. In such case, there can be a common thermal control device base 2, for example a common heat exchanger housing. The tubing 20 then is enabled to run along the housing and be securely attached to it at selected intervals. In particular, a combination of embodiments of FIGS. 3 and 6 could accommodate a complicated path of the tubing 20.

In one aspect, an electric vehicle comprising a thermal control device 1 as described above is envisaged.

FIG. 11 shows a method 100 of connecting of a tubing 20 to a thermal control device 1 according to the invention. The method 100 comprises providing 101 a connection block 10 with a connection block receiving section 11 having connection block grooves 12a, 12b. Next, the tubing 20 is provided 102. Subsequently, the tubing 20 is fixed to the connection block. The tubing 20 may be brazed to the connection block 10, in which case fixing thereof comprises aligning 103 the tubing 20 in the connection block 10 so that at least a portion of a tubing side wall 23 is in contact with the connection block receiving section 11. Subsequently, the connection block 10 and the tubing 20 are brazed 104 together. Alternatively, the tubing 20 may be fixed 105 to the connection block by screwing the tubing 20 into the connection block 10. Next, the connection block 10 is attached 106 to the thermal control device 1 (i.e. to the thermal control device base 2). The connection block 10 may be brazed to a thermal control device base 2 or it can be attached thereto mechanically, e.g. using screws 3.

Other variations to the disclosed embodiments can be understood and effected by those skilled in the art in practicing the claimed invention, from a study of drawings, the disclosure, and the appended claims. The mere fact that certain measures are recited in mutually different dependent claims does not indicate that a combination of these measures cannot be used to the advantage.

1. A thermal control device, comprising:
a thermal control device base;
a connection block attached to the thermal control device base;
a tubing for a heat exchange fluid attached to the connection block, with the tubing having a tubing extension axis and a tubing side wall; and
wherein the connection block includes a connection block receiving section, including connection block grooves, for receiving a part of the tubing side wall.

2. The thermal control device according to claim 1, wherein the connection block grooves run substantially parallel to the tubing extension axis.

3. The thermal control device according to claim 1, wherein the tubing has tubing inner grooves on a tubing inner surface.

4. The thermal control device according to claim 1, wherein the tubing has tubing outer grooves on a tubing outer surface.

5. The thermal control device according to claim 1, wherein the connection block receiving section includes an open trough.

6. The thermal control device according to claim 1, wherein the connection block receiving section includes a through-hole.

7. The thermal control device according to claim 6, wherein the tubing is divided into a first tube with a first tube extension axis and a second tube with a second tube extension axis, with the first tube and the second tube being received at the connection block receiving section and being connected fluidly by the connection block.

8. The thermal control device according to claim 7, wherein the first tube extension axis is collinear with the second tube extension axis.

9. The thermal control device according to claim 7, wherein the first tube extension axis is perpendicular to the second tube extension axis.

10. The thermal control device according to claim 7, wherein the first tube and the second tube are connected to the connection block receiving section by a threaded connection.

11. The thermal control device according to claim 1, wherein the connection block is mechanically attached to the thermal control device.

12. The thermal control device according to claim 1, wherein the connection block is brazed to the thermal control device.

13. An electric vehicle, comprising:
a thermal control device including:
a thermal control device base;
a connection block attached to the thermal control device base;
a tubing for a heat exchange fluid attached to the connection block, with the tubing having a tubing extension axis and a tubing side wall; and
wherein the connection block includes a connection block receiving section, including connection block grooves, for receiving a part of the tubing side wall.

14. A method of connecting of a tubing to a thermal control device, comprising:
providing a connection block with a connection block receiving section including grooves; providing the tubing;
fixing the tubing to the connection block; and
attaching the connection block to the thermal control device.

15. The method according to claim 14, wherein fixing the tubing includes aligning the tubing in the connection block so that at least a portion of a tubing side wall contacts the receiving section of the connection block and brazing the tubing and the connection block together.

16. The method according to claim 14, wherein fixing the tubing includes screwing the tubing into the connection block receiving section.

17. The method according to claim 14, wherein the tubing includes a first tube and a second tube, with the first tube and the second tube being independently attached to the connection block receiving section.
